(19) United States
(12) Patent Application Publication
(10) Pub. No.: US 2001/0049177 A1
(43) Pub. Date: Dec. 6, 2001

(54) Method for manufacturing semiconductor devices

(75) Inventor: Nobutaka Nagai, Tokyo (JP)

Correspondence Address: Norman P. Soloway, HAYES, SOLOWAY, HENNESSEY, GROSSMAN & HAGE, P.C., 175 Canal Street, Manchester, NH, 03101, US

(73) Assignee: NEC Corporation

(21) Appl. No.: 09/872,683

(22) Filed: Jun. 1, 2001

(30) Foreign Application Priority Data
Jun. 2, 2000 (JP) 166869/2000

(51) Int. Cl. H01L 21/8242; H01L 21/20

(52) U.S. Cl. 438/396; 438/244; 438/253

(57) ABSTRACT

There is provided a semiconductor device manufacturing method, in which a thin film made of a conductive film or an insulator film is formed on a substrate and then alignment is repeated using photolithography to thereby manufacture a DRAM. In this method, using a third photo-resist film as a mask, an opaque titanium nitride film as an upper capacitor electrode film is removed and then, a fourth photo-resist film is formed in alignment with an alignment mark on the substrate via a first inter-layer insulator film. After this, an upper capacitor electrode is formed using the fourth photo-resist film.

### BACKGROUND OF THE INVENTION

1. Field of the Invention

The present invention relates to a method for manufacturing semiconductor devices and, more particularly to, a method for manufacturing semiconductor devices intended to improve an alignment accuracy in manufacturing of the semiconductor devices by use of photolithography.

The present application claims priority of Japanese Patent Application No.2000-166869 filed on Jun. 2, 2001, which is hereby incorporated by reference.

2. Description of the Related Art

An LSI (Large Scale Integration) known as a representative of semiconductor devices are roughly classified to memory devices and logic devices, the former of which has been developed remarkably with an advancement of recent semiconductor device manufacturing technologies. Those semiconductor memory devices are grouped into DRAMs (Dynamic Random Access Memories) and SRAMs (Static Random Access Memories) and are mostly made up of MOS—(Metal Oxide Semiconductor) type transistors excellent in integration density. Also, as compared to SRAM, which are DRAM can enjoy this advantage in integration density to thereby cut down costs, thus finding wide application in a variety of memory apparatuses in information equipment or a like.

In the DRAM, each memory cell comprises one memory cell transistor and a capacitor (capacitive element) connected thereto, to store information due to existence or non-existence of charge in the capacitor. Such capacitor generally employs an MIM (Metal Insulator Metal) structure in which a capacitor insulator film has a pair of metal electrodes attached to its both sides or an MIS (Metal Insulator Silicon) structure.

The DRAM, which thus stores information using the capacitor, tends to have a smaller size, so-called device size, of a memory cell formed on a semiconductor substrate with an increasing storage quantity of information caused by an increasing integration density, which necessarily limits an area occupied by each capacitor. Accordingly, a capacitance of each capacitor must be increased within a thus limited occupation area. An insufficiency in capacitance of the capacitor for storage of information may lead to malfunctioning due to an external noise signal or a like, thus easily giving rise to an error represented by a soft error.

FIG. 4 is a cross-sectional view for showing a memory configuration of a conventionally known DRAM. As shown, in this DRAM, on a P-type silicon substrate 51, for example, a known LOCOS (LOCal Oxidation of Silicon) or STI (Shallow Trench Isolation) method is used to locally form a field insulator film, element isolating insulator film made of a silicon oxide (SiO₂) film, so that in an element forming region surrounded by this element isolating insulator film 52 are subsequently formed a gate insulator film 53 made of a silicon oxide film and a gate electrode (word line) 54 made of a poly-silicon film, in such a manner that both the gate insulator film 53 and the gate electrode 54 have their side surfaces covered by a side wall insulator film 55 made of a silicon nitride (Si₃N₄). Also, around the gate electrode 54 on a surface of the P-type silicon substrate 51, an N-type diffused region 56 for forming source or drain regions therein is locally formed and its surface as well as the surface of the gate electrode 54 are both covered by a first inter-layer insulator film 57 made of a silicon oxide film. One such gate electrode 54 and a plurality of such N-type diffused regions 56 make up in combination an MOS-type memory cell transistor 60.

In desired portions (for example, right and left portions) of the first inter-layer insulator film 57 thus formed on the surface of the N-type diffused region 56 is formed a first contact hole 58, in which a capacitor contact 59 is formed which is made of poly-silicon. On this capacitor contact 59 is formed a lower capacitor electrode 62 made of poly-silicon, above which is formed via a capacitor insulator film 63 an upper capacitor electrode 64 made of titanium nitride (TiN). The capacitor insulator film 63 may be made of a known insulator film such as, a silicon oxide film, silicon nitride film, tantalum oxide (Ta₂O₅) or a like. The lower capacitor electrode 62, capacitor insulator film 63, and upper capacitor electrode 64 make up in combination a capacitor 65, which is in turn connected through the capacitor contact 59 to the N-type diffused region 56 of the MOS-type memory cell transistor 60.

The surface of the first inter-layer insulator film 57 including the capacitor 65 is covered by a second inter-layer insulator film 67 made of a silicon oxide film, then, in a desired portion (for example, central portion) through the first inter-layer insulator film 57 and the second inter-layer insulator film 67 on the surface of the N-type diffused region 56 is formed a second contact hole 68, in which is formed a bit contact 69 made of poly-silicon. On this bit contact 69, a bit line 71 made of a titanium nitride film is formed, including which the surface of the second inter-layer insulator film 67 is then covered by a protective insulator film 72 formed of a silicon oxide film.

Now, the MOS-type memory cell transistor 60 and the capacitor 65 connected thereto make up in combination a memory cell 70.

In the manufacturing of the above-mentioned DRAM, processes are repeated for patterning films made of a variety of conductive films or insulator films formed on the P-type substrate 51 into desired shapes, each patterning step using a known photolithographic technology.

In carrying out the photolithographic method in each patterning step, it is necessary to use an alignment (positional alignment) mark or an alignment reference position already formed on the P-type silicon substrate 51 in a previous step to thereby align a photo-mask used in the photolithographic method for the relevant patterning with that alignment mark or reference position.

Since in this alignment step, some misalignment cannot be avoided due to limitations of mechanical accuracy, this misalignment must be reduced as much as possible to improve alignment accuracy in order to provide for reduction of device size, thus resulting in a higher integration density. Also, the more the film layers made of conductive films or insulator films formed on the P-type silicon substrate 51 in a series of manufacturing processes, the more must the alignment process be repeated and hence the larger will be an overall misalignment.

The following will describe a prior art method for manufacturing the DRAM along its steps with reference to FIGS. 6A-6J. In this description, taking into account a general fine patterning technological accuracy level in photolithography, an alignment margin (largest permissible misalignment) for each alignment step is set at about 0.06 μm and such a case is assumed that the P-type silicon substrate 51 is expected to encounter a largest misalignment in a same direction when a plurality of alignment steps is carried out.

First, as shown in FIG. 6A, for example, the P-type silicon substrate 51 is used to locally form thereon the element isolating insulator film 52 made of a silicon oxide film using known LOCOS or STI method. Next, on the surface of the P-type silicon substrate 51 is formed a silicon oxide film using thermal oxidation, on which is then formed a poly-silicon film using a CDV (Chemical Vapor Deposition) or sputtering method, so that those silicon oxide and poly-silicon films are then patterned into desired shapes using photolithography to form the gate oxide film 53 and the gate electrode 54 in an element forming region 74. At the same time, in a scribe region 75 are formed alignment marks 76 and 77 made of a film stack combining a silicon oxide film 53A and a poly-silicon film 54A. Next, a silicon nitride film is formed throughout on the surface of the P-type silicon substrate 51 by CVD or sputtering and then an unnecessary portion of the silicon nitride film is removed using an etch-back method to form a side wall insulator film 55. Next, using the gate electrode 54 as a mask, ions of an N-type impurity are implanted into the P-type silicon substrate 51 to form the N-type diffused region 56 expected to be a source or drain region.

Next, as shown in FIG. 6B, throughout on the surface of the P-type silicon substrate 51 is formed the first inter-layer insulator film 57 made of a silicon oxide film by CVD or sputtering, on which is then formed a first photo-resist film 78 for forming a capacitor contact to be formed on this first inter-layer insulator film 57. To do so, first the photo-resist is applied throughout on the surface and then a photo-mask (not shown) is aligned with one alignment mark 77 (first alignment) via the transparent first inter-layer insulator film 57 to carry out patterning using exposure and development processes, thus forming the first photo-resist film 78. This first photo-resist film 78 has openings 78A and 78B formed in the element forming region 74 (FIG. 6A) and also openings 78C and 78D formed in the scribe region 75 (FIG. 6A) . The positions of those openings 78A-78D are mis-aligned, due to the above-mentioned setting, from the alignment mark 77 rightward on the P-type silicon substrate 51 by as much as a dimension d of about 0.06 μm. A reference numeral 73 indicates a position free of misalignment.

Next, as shown in FIG. 6C, using the first photo-resist film 78 as a mask, the first inter-layer insulator film 57 is locally dry-etched to form the first contact hole 58 which exposes the diffused regions 56 on the right and left sides of the element forming region 74 (FIG. 6A) respectively and also to form holes 61 in the scribe region 75 (FIG. 6A).

Next, after the first photo-resist film 78 is removed, as shown in FIG. 6D, a poly-silicon film is formed throughout on the surface using CVD or sputtering and then the unnecessary portion of this poly-silicon film is removed by etch back to form the capacitor contact 59 in the first contact hole 58. Next, a poly-silicon film (lower electrode film) 62A is formed throughout on the surface by CVD or sputtering and then on this poly-silicon film 62A is formed a second photo-resist film 79 for forming the lower electrode. To do so, first a photo-resist (not shown) is applied throughout on the surface and then a photo-mask (not shown) is aligned with the hole 61 in the first inter-layer insulator film 57 (second alignment) to carry out patterning using exposure and development processes, thus forming the second photo-resist film 79. The position of this second photo-resist film 79 is mis-aligned, due to the above-mentioned setting, from the hole 61, that is the second alignment reference position, rightward on the P-type silicon substrate 51 by as much as a dimension d of about 0.06 μm.

Next, as shown in FIG. 6E, using the second photo-resist film 79 as a mask, the poly-silicon film 62A is locally dry-etched to form the lower capacitor electrode 62 on the right and left capacitor contacts 59 in the element forming region 74, while leaving part of poly-silicon film 62A un-etched in the scribe region 75 (FIG. 6A).

Next, after the second photo-resist film 79 is removed, as shown in FIG. 6F, the capacitor insulator film 63 is formed made of a silicon oxide, silicon nitride, tantalum oxide film or a like throughout on the surface by CVD or sputtering and its unnecessary portion is removed by patterning to thereby leave the necessary part un-removed on the lower capacitor electrode 62. Next, a titanium nitride film (upper capacitor electrode film) 64A is formed throughout on the surface by CVD or sputtering, on which is then formed a third photo-resist film 80 for forming the upper capacitor electrode. To do so, first, a photo-resist (not shown) is applied throughout on the surface and then a photo-mask (not shown) is aligned to the poly-silicon film 62A (third alignment) to carry out patterning using exposure and development processes, thus forming the third photo-resist film 80. In this case of alignment, since the titanium nitride film 64A is opaque, alignment with the alignment mark 76 or 77 is impossible through this titanium nitride film 64A. The position of the third photo-resist film 80 is mis-aligned, due to the above-mentioned setting, from the third alignment reference position, that is, the poly-silicon film 62A, rightward on the P-type silicon substrate 51 by as much as the dimension d of about 0.06 μm.

Next, as shown in FIG. 6G, using the third photo-resist film 80 as a mask, the titanium nitride film 64A is locally dry-etched to form the upper capacitor electrode 64 on the capacitor insulator films 63 formed on the right and left sides of the element forming region 74 FIG. 6A respectively, while leaving part of the titanium nitride film 64A un-etched in the scribe region 75 (FIG. 6A).

Next, after the third photo-resist film 80 is removed, as shown in FIG. 6H, the second inter-layer insulator film 67 made of a silicon oxide film is formed by CVD or sputtering and then a fourth photo-resist film 81 is formed for forming a bit contact on this second inter-layer insulator film 67. To do so, first a photo-resist (not shown) is applied throughout on the surface and then a photo-mask (not shown) is aligned with the other alignment mark 76 (fourth alignment) to carry out patterning using exposure and development processes, thus forming the fourth photo-resist film 81. This fourth photo-resist film 81 has an opening 81A formed in the element forming region 74 (FIG. 6A) and also an opening 81B formed in the scribe region 75 (FIG. 6A). In this step, the positions of those openings 81A and 81B are mis-aligned from the alignment mark 76 leftward on the P-type silicon substrate 51 by as much as the dimension d of about 0.06 μm. In this step, this possible leftward mis-alignment of the fourth photo-resist film 81 must be taken into account in order to meet the condition that a later-described bit line should not be short-circuited to the upper capacitor electrode 64 even with the largest misalignment.

Next, as shown in FIG. 6I, using the fourth photo-resist film 81 as a mask, both the second inter-layer insulator film 67 and the first inter-layer insulator film 57 are locally dry-etched to form the second contact hole 68 which exposes the central diffused region 56 in the element forming region 74 (FIG. 6A) at the same time as forming a hole 66 in the scribe region 75 (FIG. 6A).

Next, after the fourth photo-resist film 81 is removed, as shown in FIG. 6J, a poly-silicon is formed throughout on the surface by CVD or sputtering and then its unnecessary portion is removed by etch-back to form the bit contact 69 in the second contact hole 66 (FIG. 6I). Next, the bit line 71 made of a titanium nitride film is formed throughout on the surface by CVD or sputtering to then form the protective insulator film 72 (FIG. 4) made of a silicon oxide film on the second inter-layer insulator film 67 including the bit line 71 by CVD or sputtering. Next, the P-type silicon substrate 51 is scribed off along the scribe region 75 (FIG. 6A) into individual chip dice, thus completing the DRAM shown in FIG. 4.

FIG. 2 shows an alignment flowchart for the above-mentioned prior art DRAM manufacturing method in comparison to a method according to the present invention. An alignment flowchart for the present invention is described later. The prior art alignment flowchart indicates a rule of thumb for the magnitude of mis-alignment in a case where processes shown therein are sequentially carried out using as a first reference position the alignment marks 76 and 77 (FIG. 6A) formed simultaneously with the gate electrode 54 (FIG. 6A).

In manufacturing a DRAM by repeating the above-mentioned alignment step, a difference in device size between the prior art and the present invention (described later) is determined by a distance L between the capacitor contact 59 and the bit contact 69. This distance L is in turn given as a sum of a distance (separating distance) L1 between the upper electrode 64 and the bit contact 69 and a distance (overlapping distance) L2 of the capacitor contact 59 and the upper electrode 64. Assuming that no misalignment is produced in the prior art manufacturing method, a DRAM having such a configuration as shown in FIG. 10 is made with the distances L1 and L2 being given as follows:

Distance L1=0.06 μm×4 misalignment times (due to first to fourth alignment steps)+0.02 μm=0.26 μm where a value of 0.02 μm represents a margin (+α) added for preventing short-circuiting.

Distance L2=0.06 μm×2 misalignment times (first and second alignment steps)+0.02 μm=0.14 μm

Therefore, the following will be given:

Distance L=distance L1+distance L2=0.40 μm

That is, in manufacturing of a DRAM according to the prior art, when no misalignment is assumed, DRAM device size takes on a value which reflects the above-mentioned value of 0.40 μm.

To reduce such the DRAM device size, it is necessary to improve alignment accuracy in order to reduce the above-mentioned distance L, which has been difficult by the prior art manufacturing method because it has the opaque titanium nitride film 64A formed as the upper capacitor electrode film over the alignment marks 76 and 77, which limits alignment accuracy.

The above-described DRAM manufacturing method by use of photolithography configured to detect the alignment marks accurately is disclosed for example in Japanese Patent Application Laid-Open No. Hei 11-289015.

In this DRAM manufacturing method, aimed at appropriate alignment in flattening of films made of a conductive film or an insulator film by use of, in particular, a CMP (Chemical Mechanical Polishing) method, to carry out photolithography after CMP easily and securely, such processes are utilized so as to form an element isolating insulator film in an element forming region or to form a transistor, thus forming a protrusive alignment mark in a recess in a scribe region. By such a configuration, even if CMP is carried out after substrate is covered by a thin film thoroughly, the alignment mark can be detected accurately because that alignment mark is reflected on a surface of the thin film in the scribe region.

By the semiconductor device manufacturing method disclosed in the Japanese Patent Application Laid-open No. Hei 11-289015, however, if the alignment mark is formed in the recess in the scribe region and then the surface is entirely covered by the thin film and then CMP is carried out, the surface of the scribe region is flattened, thus problematically making it difficult to reflect the alignment mark on the surface of the thin film in the scribe region.

That is, by that semiconductor device manufacturing method disclosed in that publication, even if a protrusive alignment mark is formed in the recess in the scribe region, when the surface is covered by a thin film and then CMP is carried out, the surface of an inter-layer insulator film 15 actually does not have a shape that reflects thereon the protrusion of an alignment mark 14 and so is flattened as shown in FIG. 2A of that publication.

Therefore, like a case of the prior art semiconductor device manufacturing method described with reference to FIGS. 4-6J, when an opaque metal film such as a titanium nitride film is formed to provide the upper capacitor electrode in the element forming region, the alignment mark is covered by that opaque metal film to thereby inflict limitations on the alignment accuracy, thus making it difficult to reduce device size.

### SUMMARY OF THE INVENTION

In view of the above, it is an object of the present invention to provide a method for manufacturing semiconductor devices that can reduce a device size without limitations on alignment accuracy even if an alignment mark is covered by an opaque metal film.

According to a first aspect of the present invention, there is provided a semiconductor manufacturing method for forming a thin film made of a conductive film or an insulator film on a semiconductor substrate and then repeating alignment using photolithography to thereby pattern the thin film into a desired shape in order to form a memory cell comprised of a memory cell transistor and a capacitor on the semiconductor substrate, including:

an alignment mark forming step for simultaneously forming a main portion of the memory cell transistor and an alignment mark in an element forming region and another region respectively on the semiconductor substrate;

a capacitor contact forming step for forming an inter-layer insulator film throughout on a surface of the semiconductor substrate and covering the inter-layer insulator film with a photo-resist film formed in alignment with the alignment mark and then locally removing the inter-layer insulator film using the photo-resist film as a mask to thereby form a contact hole which exposes a desired diffused region of the memory cell transistor and then forms a capacitor contact in the contact hole;

a thin film forming step for sequentially forming a lower capacitor electrode film, a capacitor insulator film, and an upper capacitor electrode on the inter-layer insulator film in order to form a capacitor connected to the capacitor contact; and

an upper capacitor electrode film removing step for covering the inter-layer insulator film with another photo-resist film except a region above the alignment mark of the upper capacitor electrode film and then locally removing the upper capacitor electrode film using the photo-resist film as a mask to thereby expose the inter-layer insulator film.

According to a second aspect of the present invention, there is provided a semiconductor manufacturing method for forming a thin film made of a conductive film or an insulator film on a semiconductor substrate and then repeating alignment using photolithography to thereby pattern the thin film into a desired shape in order to form a memory cell comprised of a memory cell transistor and a capacitor on the semiconductor substrate, including:

an alignment mark forming step for simultaneously forming a main portion of the memory cell transistor and an alignment mark in an element forming region and another region respectively on the semiconductor substrate;

a capacitor contact forming step for forming a first inter-layer insulator film throughout on a surface of the semiconductor substrate and covering the first inter-layer insulator film with a first photo-resist film formed in alignment with the alignment mark and then making an opening in the first inter-layer insulator film using the first photo-resist film as a mask to thereby form a first contact hole which exposes a desired diffused region of the memory cell transistor and then forms a capacitor contact in the first contact hole;

a lower capacitor electrode forming step for forming a lower capacitor electrode film on the first inter-layer insulator film in such a manner that the lower capacitor film may be connected to the capacitor contact and then covering the lower capacitor electrode film with a second photo-resist film formed in alignment with the opening in the first inter-layer insulator film and then locally removing the lower capacitor electrode film using the second photo-resist film as a mask to thereby form a lower capacitor electrode;

an upper capacitor electrode film removing step for sequentially forming a capacitor insulator film and an upper capacitor electrode film on the lower capacitor electrode and then covering the inter-layer insulator film with a third photo-resist film except a region above the alignment mark of the upper capacitor electrode film and then locally removing the upper capacitor electrode film using the third photo-resist film as a mask to thereby expose the first inter-layer insulator film;

an upper capacitor electrode forming step for covering the upper capacitor electrode film with a fourth photo-resist film formed in alignment with the alignment mark on the semiconductor substrate and then locally removing the upper capacitor electrode film using the fourth photo-resist film as a mask to thereby form an upper capacitor electrode; and

a bit contact forming step for forming a second inter-layer insulator film on the first inter-layer insulator film and then covering the second inter-layer insulator film with a fifth photo-resist film formed in alignment with the alignment mark and then making an opening in the first and second inter-layer insulator films using the fifth photo-resist film as a mask to thereby form a second contact hole which exposes a desired diffused region of the memory cell transistor and then forms a bit contact in the second contact hole.

In the foregoing first and second aspects, a preferable mode is one wherein the memory cell transistor and the alignment mark are formed in an element forming region and a scribe region respectively on the semiconductor substrate.

Also, a preferable mode is one wherein the alignment mark is formed at the same time as a gate electrode of the memory cell transistor is formed.

Also, a preferable mode is one wherein the alignment mark is formed in a number of two or more.

Also, a preferable mode is one wherein after the bit contact is formed, a bit line is formed in such a manner that the bit line may be connected to the bit contact.

Furthermore, a preferable mode is one wherein the bit line is formed above the upper capacitor electrode.

With the above configuration, when a thin film made of a conductive film or an insulator film is formed on a substrate to then repeat alignment using lithography in order to manufacture a semiconductor device, a photo-resist film is used as a mask to remove an opaque metal film as an upper capacitor electrode film and then another photo-resist film formed in alignment with an alignment mark on the substrate via an inter-layer insulator film is used to form an upper capacitor electrode, thus reducing a misalignment.

Therefore, even if the alignment mark is covered by the opaque metal film, no limitations are inflicted on alignment, thus reducing device size.

### BRIEF DESCRIPTION OF THE DRAWINGS

The above and other objects, advantages, and features of the present invention will be more apparent from the following description taken in conjunction with the accompanying drawings, in which: FIGS. 1A-1L are process drawings for showing a configuration of a semiconductor device manufacturing method according to one embodiment of the present invention along its steps;

FIG. 2 is an alignment flow chart for indicating the principle of the present invention;

FIG. 3 is a cross-sectional view for showing a semiconductor device manufactured by the present semiconductor device manufacturing method;

FIG. 4 is a cross-sectional view for showing a configuration of a prior art semiconductor device;

FIG. 5 is another cross-sectional view for showing the prior art semiconductor device; and

FIGS. 6A-6J are process drawings for showing a prior art semiconductor device manufacturing method along its steps.

### DESCRIPTION OF THE PREFERRED EMBODIMENTS

Best modes of carrying out the present invention will be described in further detail using various embodiments with reference to the accompanying drawings.

FIGS. 1A-1L are process drawings for showing a semiconductor device manufacturing method according to an embodiment of the present invention. The following will describe this semiconductor device manufacturing method with reference to FIGS. 1A-1L. Like in the case of a prior art method, for this embodiment also, taking into account a typical fine patterning accuracy level by photolithography, such a case is described that may produce a largest misalignment which would possibly occur in a same direction on a P-type silicon substrate 1 when alignment is carried out a plurality of number of times with each-time alignment margin (largest misalignment) being set at about 0.06 μm.

First, as shown in FIG. 1A, on the P-type silicon substrate 1, for example, an element isolating insulator film 2 made of a silicon oxide film is locally formed by a known LOCOS or STI method. Next, on the surface of the P-type silicon substrate 1 is formed by thermal oxidation a silicon oxide film to a thickness of 2-12 nm, on which is then formed by CVD or sputtering a poly-silicon film to a thickness of 80-300 nm, so that those silicon oxide film and poly-silicon film are subsequently patterned into desired shapes by photolithography to thereby form a gate insulator film 3 and a gate electrode 4 in an element forming region 24. At the same time, three alignment marks 26, 27, and 33 made of a stacked film layer combining a silicon oxide film 3A and a poly-silicon film 4A are formed in a scribe region 25. As described later, those alignment marks 26, 27, and 33 are all used as a reference for patterning of conductive films or insulator films in the subsequent processes.

Next, a silicon nitride film is formed to a thickness of 10-15 nm throughout on the surface of the P-type silicon substrate 1 by CVD or sputtering and then its unnecessary portion is removed by etch-back to form a side wall insulator film 5. Next, using the gate electrode 4 as a mask, ions of an N-type impurity are implanted into the P-type silicon substrate 1 to form an N-type diffused region 6 which provides a source or drain region.

Next, as shown in FIG. 1B, throughout on the surface of the P-type silicon substrate 1 is formed by CVD or sputtering a first inter-layer insulator film 7 made of a silicon oxide film to a thickness of 0.8-1.2 μm, on which is then formed a first photo-resist film 28 for forming a capacitor contact. To do so, first a photo-resist (not shown) is applied throughout on the surface and then a photo-mask (not shown) is aligned with one alignment mark 27 (first alignment) via transparent first inter-layer insulator film 7 to carry out patterning using exposure and development processes, thus forming the first photo-resist film 28. This first photo-resist film 28 has openings 28A and 28B formed in the element forming region 24 (FIG.1A) and openings 28C and 28D formed in the scribe region 25 (FIG.1A). The positions of those openings 28A through 28D are mis-aligned, due to the above-mentioned setting, from the alignment mark 27 rightward on the P-type silicon substrate 1 by as much as a dimension d of about 0.06 μm. A reference numeral 23 indicates a position free of misalignment.

Next, as shown in FIG. 1C, using the first photo-resist film 28 as a mask, the first inter-layer insulator film 7 is locally dry-etched to form a first contact hole 8 which exposes the diffused regions 6 on the right and left sides of the element forming region 24 (FIG. 1A) and, at the same time, to form holes 11 in the scribe region 25 (FIG. 1A).

Next, after the first photo-resist film 28 is removed, as shown in FIG. 1D, a poly-silicon film (not shown) is formed throughout on the surface by CVD or sputtering and then its unnecessary portion is removed by etch-back to form a capacitor contact 9 in the first contact hole B. Next, a poly-silicon film (lower electrode film) 12A is formed throughout on the surface by CVD or sputtering, on which is then formed a second photo-resist film 29 for forming the lower electrode. To do so, first a photo-resist film (not shown) is applied throughout on the surface and then a photo-mask (not shown) is aligned (second alignment) using the holes 11 in the first inter-layer insulator film 7 as a reference position to carry out patterning using exposure and development processes, thus forming the second photo-resist film 29. The position of this photo-resist film 29 is mis-aligned, due to the above-mentioned setting, from the hole 11, that is the second alignment reference position, rightward on the P-type silicon substrate 1 by as much as the dimension d of about 0.06 μm.

Next, as shown in FIG. 1E, using the second photo-resist film 29 as a mask, the poly-silicon film 12A is locally dry-etched to form a lower capacitor electrode 12 on the capacitor contacts 9 on the right and left sides of the element forming region 24 (FIG. 1A), while leaving part of the poly-silicon film 12A in the scribe region 25 (FIG. 1A).

Next, after the second photo-resist film 29 is removed, as shown in FIG. 1F, a capacitor insulator film 13 made of a silicon oxide, silicon nitride, tantalum oxide film or a like is formed by CVD or sputtering and its unnecessary portion is removed by patterning, so that its necessary portion is left on the lower capacitor electrode 12 (FIG. 1A). Next, a titanium nitride film 14 A (upper capacitor electrode film) 14A is formed throughout on the surface by CVD or sputtering, on which is then formed a third photo-resist film 30, through which the alignment mark can be seen. Since this third photo-resist film 30 is formed so that the alignment mark 26 on the P-type silicon substrate 1 may be seen through the first inter-layer insulator film 7, it need not be aligned so strictly, so that first the photo-resist (not shown) is applied throughout on the surface and then, without alignment of the photo-mask (not shown), patterning is carried out using exposure and development processes for formation. This third photo-resist film 30, having an opening 30A in the scribe region 25 (FIG. 1A), covers the above-mentioned first inter-layer insulator film 7 except a region above the alignment mark 26 for the titanium nitride film 14A.

Next, as shown in FIG. 1G, using the third photo-resist film 30 as a mask, the titanium nitride film 14A is locally dry-etched to expose the first inter-layer insulator film 7 in the scribe region 25 (FIG. 1A). Now, the alignment mark 26 is avoided from being covered by the titanium nitride film 14A, which is an opaque metal film. This process intends to remove only the titanium nitride film 14A, leaving the first inter-layer insulator film 7 un-removed. It is done so because, if an opening is already made in the first inter-layer insulator film 7 by etching before a second inter-layer insulator film 17 (FIG. 1K) is formed on the first inter-layer insulator film 7 in the subsequent process, the overlying second inter-layer insulator film 17 (FIG. 1K) may be affected by that opening and deteriorated in flatness.

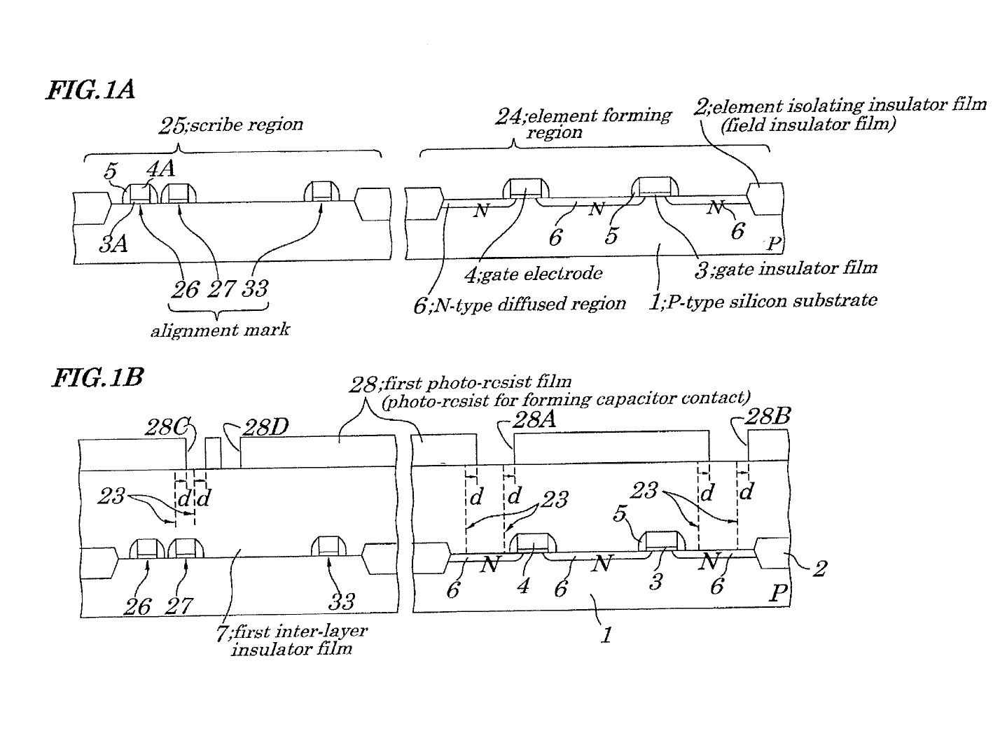

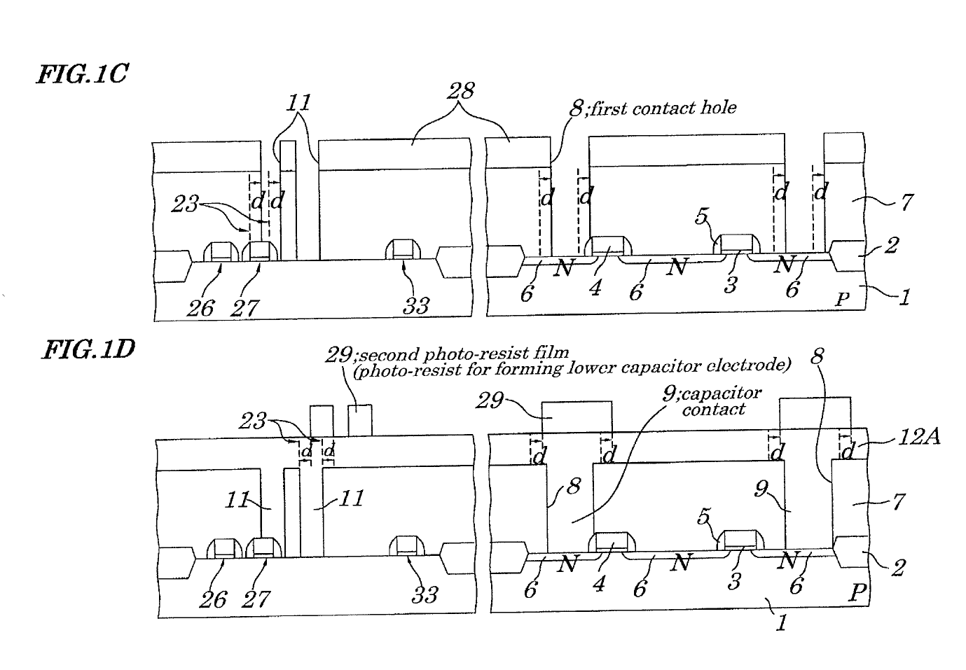

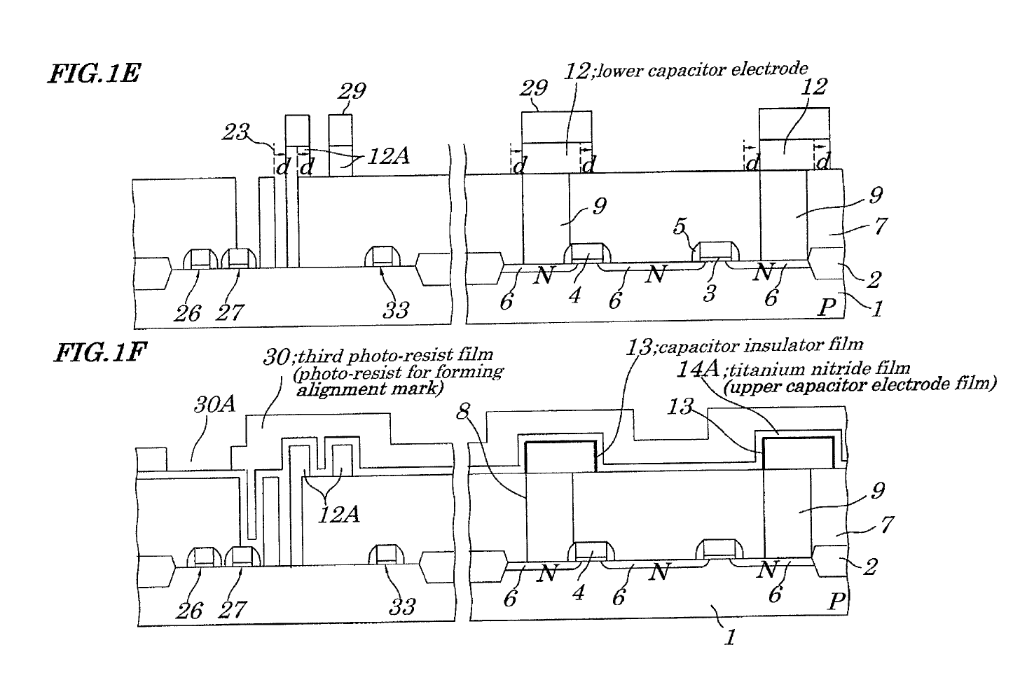

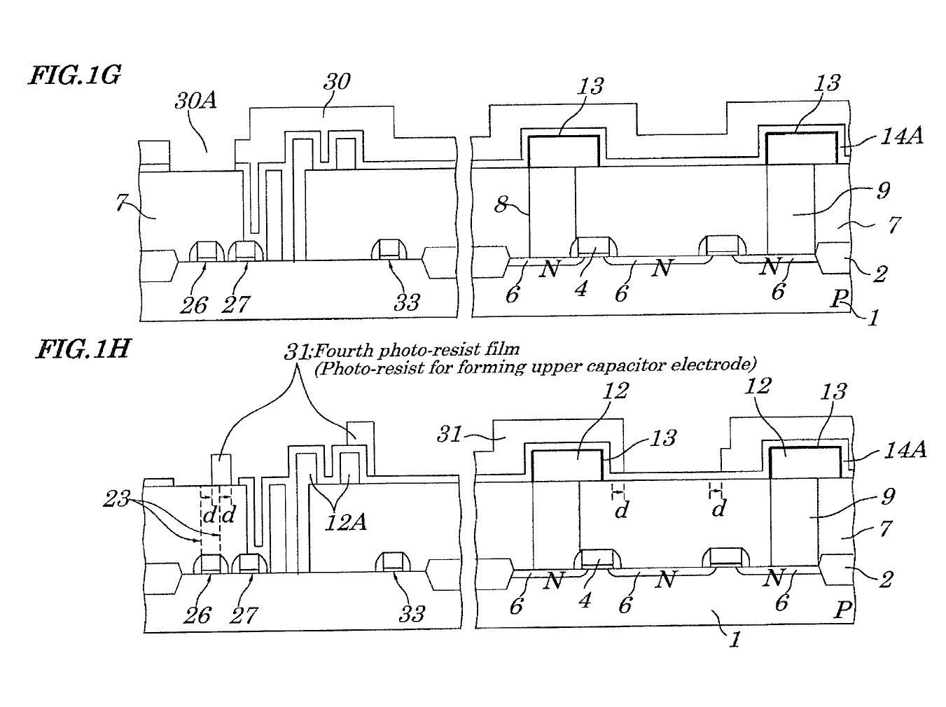

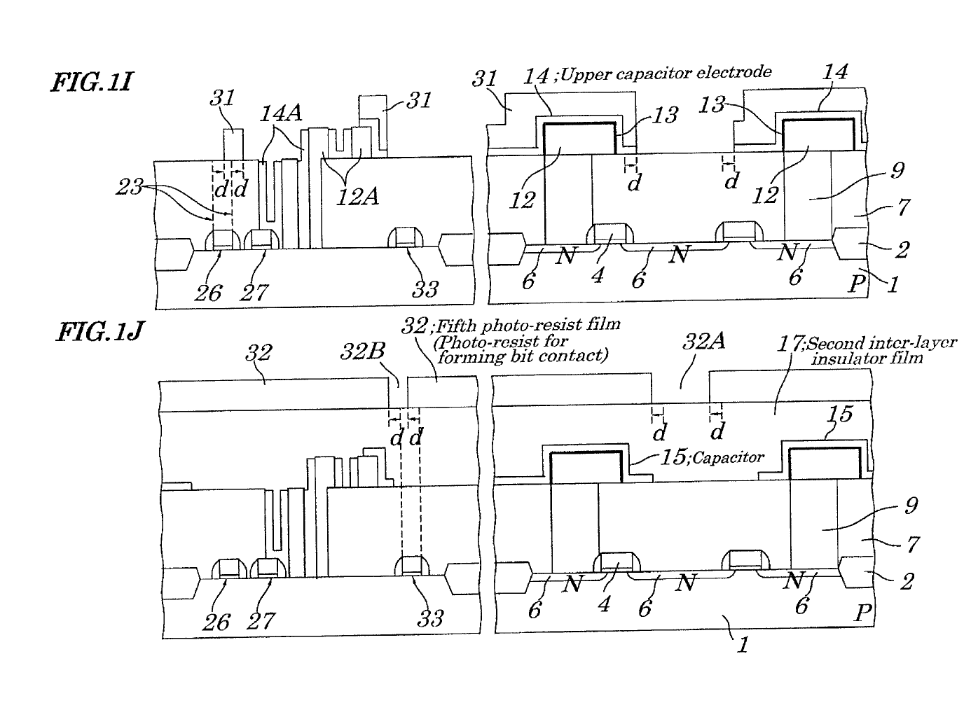

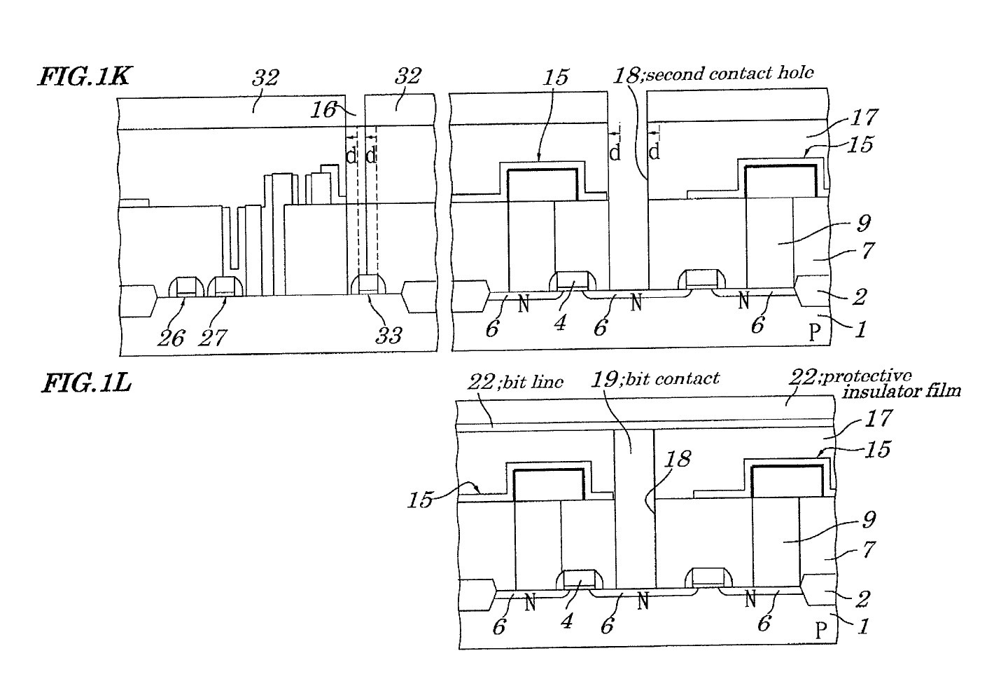

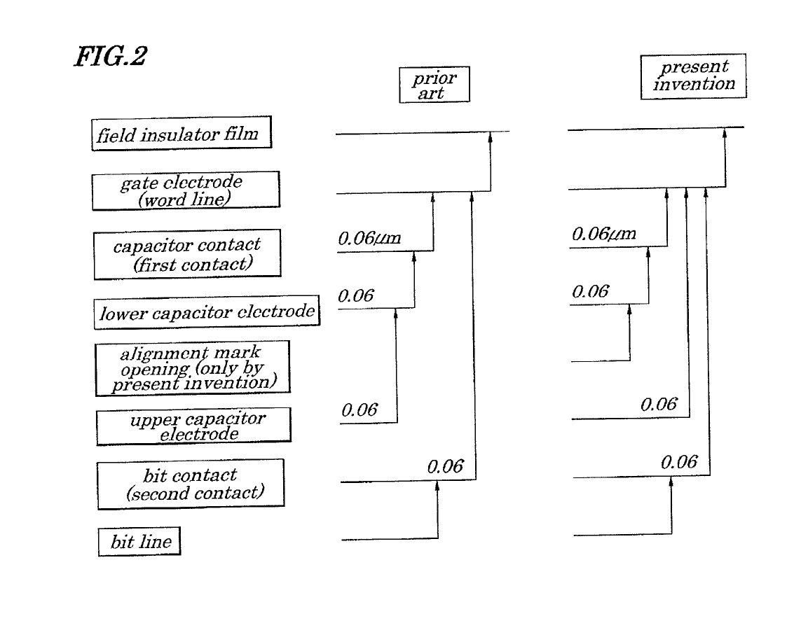

Next, after the third photo-resist film 30 is removed, as shown in FIG. 1H, a fourth photo-resist film 31 is formed on the titanium nitride film 14A for forming the upper capacitor electrode. To do so, first a photo-resist (not shown) is applied throughout on the surface and then a photo-mask (not shown) is aligned with the alignment mark 26 (third alignment) via the first inter-layer insulator film 7, to be patterned using exposure and development processes, thus forming the fourth photo-resist film 31. Since this alignment is carried out with respect to the alignment mark 26 on the P-type silicon substrate 1, as can be seen from the flowchart in FIG. 2, although another photo-lithographic process must be carried out, a misalignment can be suppressed, thus improving the alignment accuracy. The position of the fourth photo-resist film 31 is mis-aligned, due to the above-mentioned setting, from the alignment mark 26, that is the third alignment reference position, rightward on the P-type silicon substrate 1 by as much as the dimension d of about 0.06 μm.

Next, as shown in FIG. 1I, using the fourth photo-resist film 31 as a mask, the titanium nitride film 14A is locally dry-etched to form an upper capacitor electrode 14 on the capacitor insulator films 13 on the right and left sides of the element forming region 24 (FIG. 1A), while leaving part of the titanium nitride film 14A in the scribe region 25 (FIG. 1A).

Next, after the fourth photo-resist film 31 is removed, as shown in FIG. 1J, a second inter-layer insulator film 17 made of a silicon oxide film is formed throughout on the surface by CVD or sputtering, on which is then formed a fifth photo-resist film 32 for forming a bit contact. To do so, first a photo-resist (not shown) is applied throughout on the surface and then a photo-mask (not shown) is aligned with the other alignment mark 33 (fourth alignment) and patterned using exposure and development processes to form the fifth photo-resist film 32. This fifth photo-resist film 32 has an opening 32A in the element forming region 24 (FIG. 1A) and an opening 32B in the scribe region 25 (FIG. 1A) . In this process, the positions of the openings 32A and 32B are mis-aligned from the alignment mark 33 leftward on the P-type silicon substrate 1 by as much as the dimension d of about 0.06 μm. This leftward misalignment of the fifth photo-resist film 32 is thus taken into account in this process in order to meet the above-mentioned condition that the later-described bit line should not be short-circuited with the upper capacitor electrode 14 even with the largest misalignment.

Next, as shown in FIG. 1K, using the fifth photo-resist film 32 as a mask, the second inter-layer insulator film 17 and the first inter-layer insulator film 7 are locally dry-etched to form a second contact hole 18 which exposes the diffused region 6 at the center of the element forming region 24 (FIG. 1A) and, at the same time, to form a hole 16 in the scribe region 25 (FIG. 1A).

Next, after the fifth photo-resist film 32 is removed, as shown in FIG. 1L, a poly-silicon film (not shown) is formed throughout on the surface by CVD or sputtering and then its unnecessary portion is removed by etch-back to form a bit contact 19 in the second contact hole 18. Next, a bit line 21 made of a titanium nitride film is formed throughout on the surface by CVD or sputtering, on which including the second inter-layer insulator film 17 is formed a protective insulator film 22 made of a silicon oxide film. Next, the P-type silicon substrate 1 is cut off along the scribe region 25 (FIG. 1A) into individual chip dice, thus completing the DRAM.

As can be seen from the alignment flowchart in FIG. 2, by this embodiment, although a newly added alignment mark opening process increases the number of the required photolithography steps, the fourth photo-resist film 31 for forming the upper capacitor electrode 14 is formed in alignment with the alignment mark 26 via the first inter-layer insulator film 7 to thereby suppress a misalignment, thus improving the alignment accuracy.

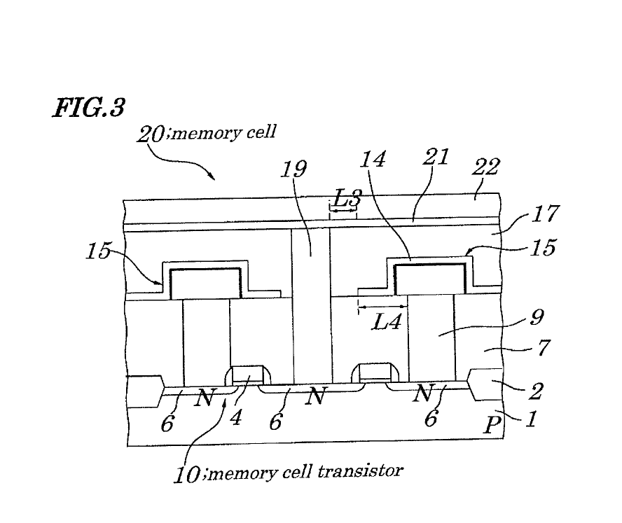

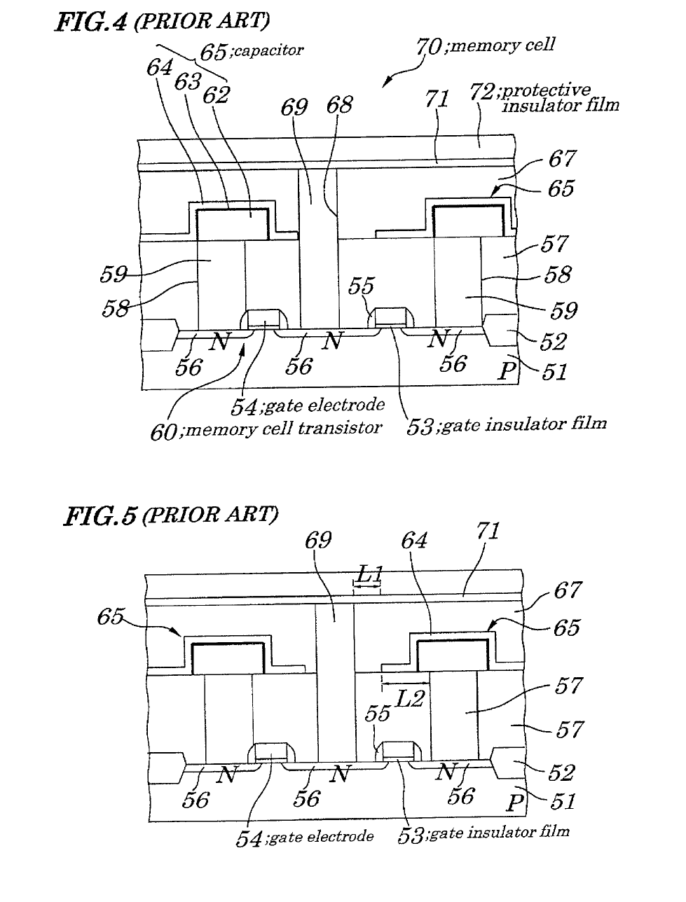

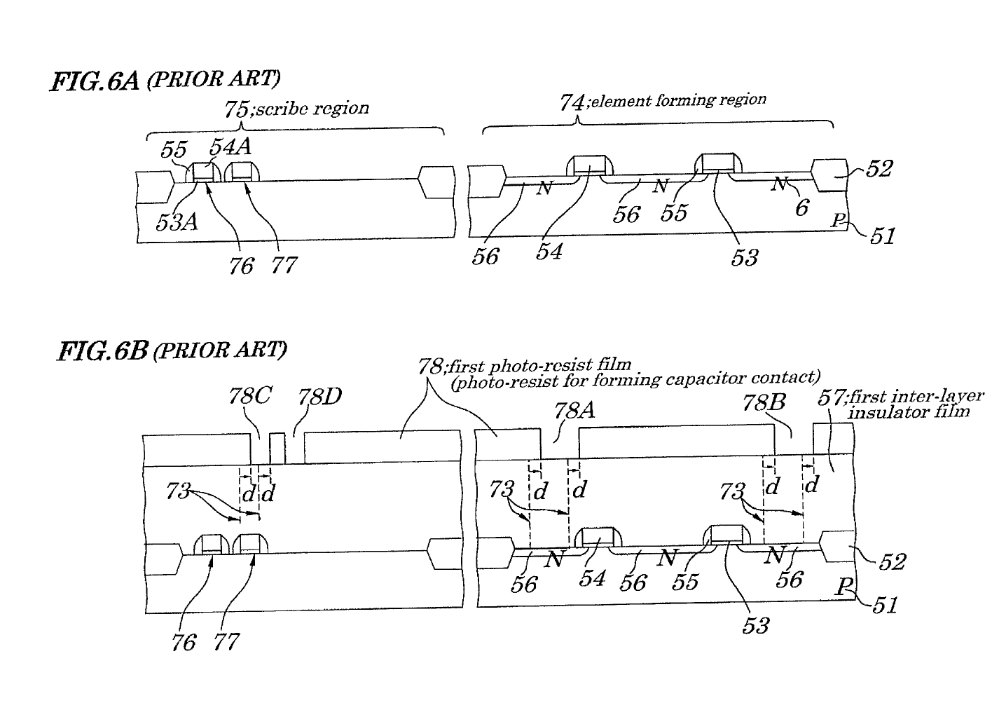

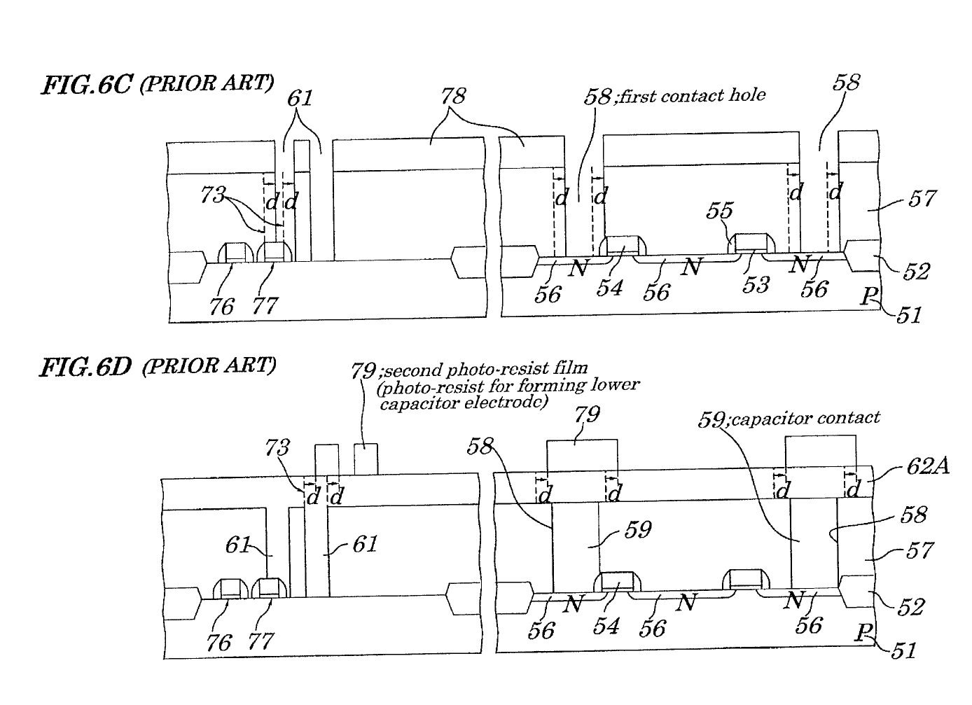

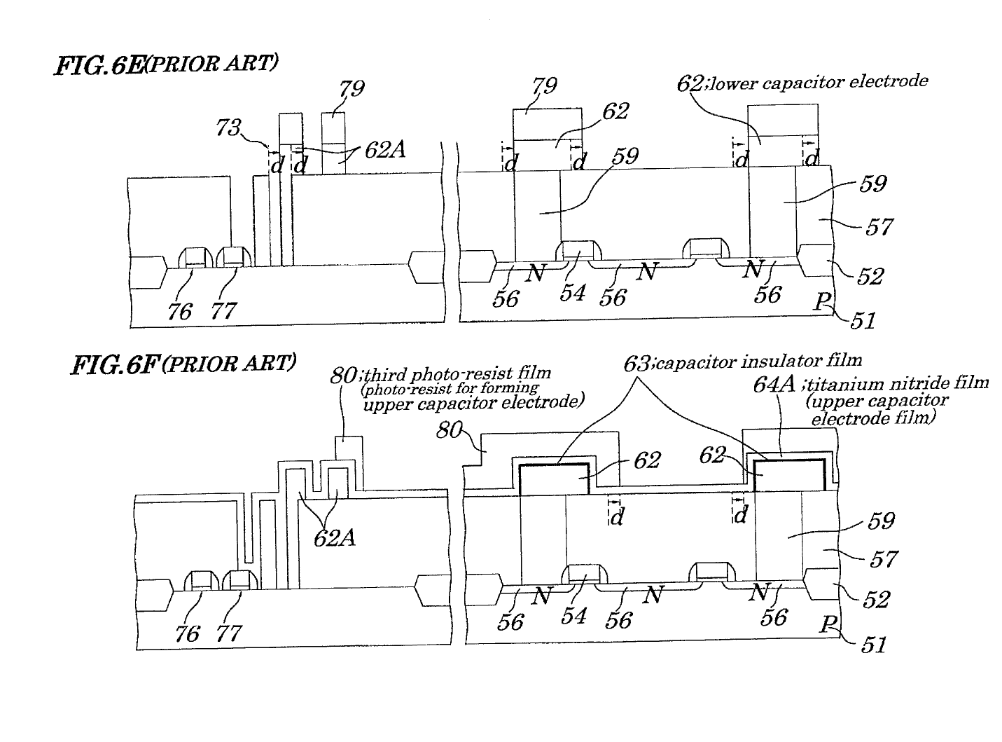

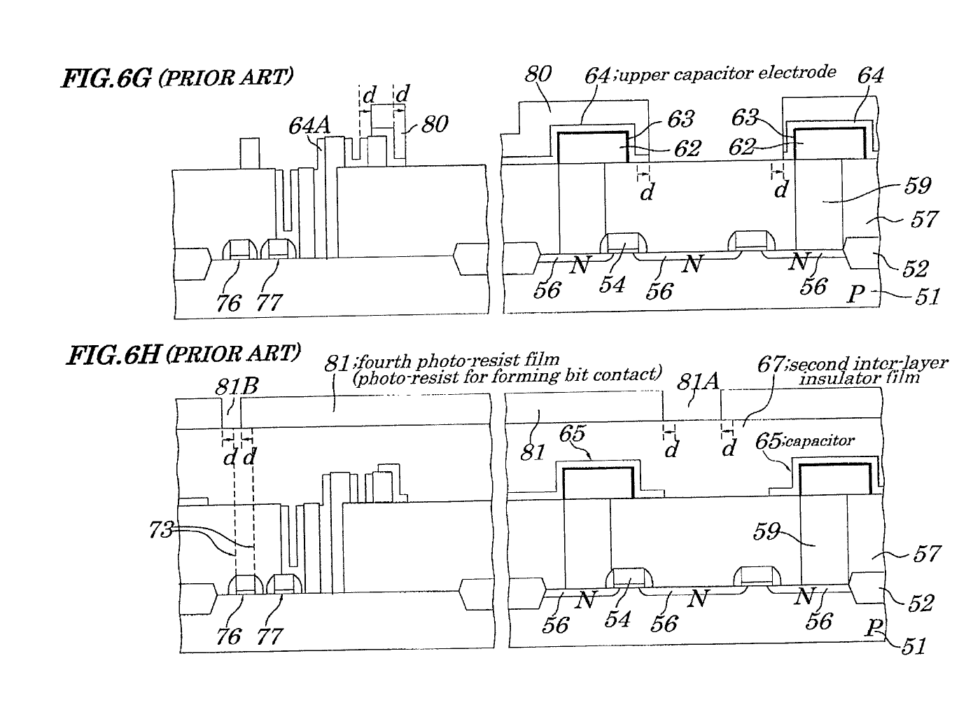

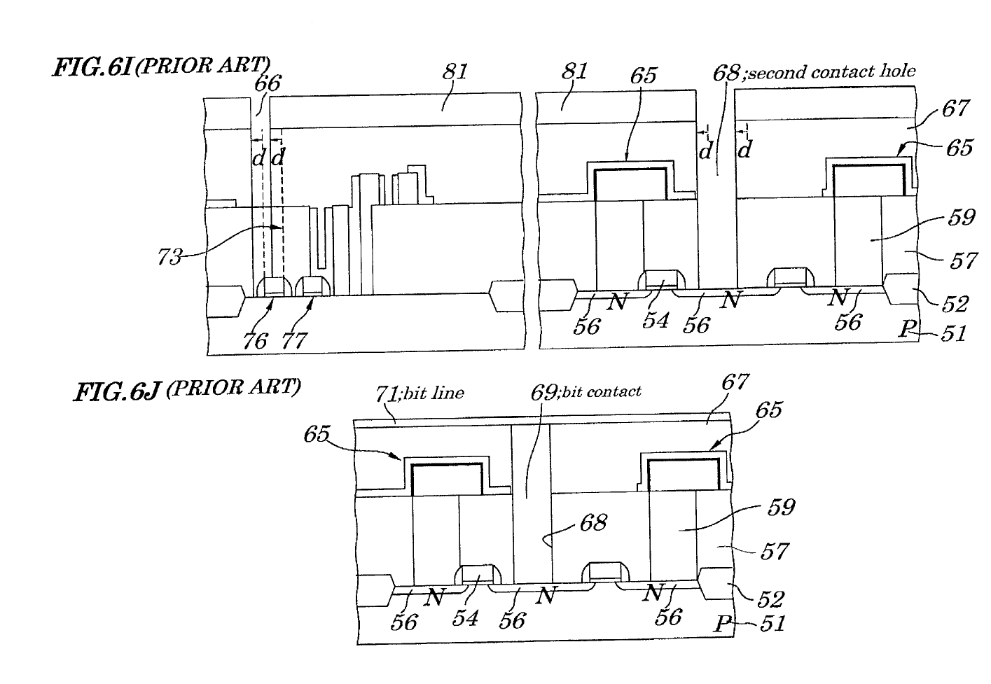

FIG. 3 shows a configuration of a DRAM manufactured by a semiconductor device manufacturing method according to this embodiment in a case where no misalignment is assumed to be produced. A difference in device size between the prior art and the present invention is determined by a distance L between the capacitor contact 9 and the bit contact 19, which distance L is in turn given by a sum of a distance (separating distance) L3 between the upper capacitor electrode 14 and the bit contact 19 and a distance (overlapping distance) L4 between the capacitor contact 9 and the upper capacitor electrode 14. Those distances LB and L4 are given as follows:

Distance L3=0.06 μm×2 misalignment times (third and fourth alignment steps)+0.02 μm=0.14 μm

Distance L4=0.06 μm×3 misalignment times (first through third alignment steps)+0.02 μm=0.20 μm

Therefore, the following will be given:

Distance L=distance L3+distance L4=0.34 μm

That is, when the DRAM is manufactured by the method according to this embodiment, if no misalignment is assumed to be produced, the number of times of misalignment encountered is five, which is fewer than the value (six) by the prior art, so that device size of the DRAM takes on a value on which the above-mentioned value of 0.34 μm is reflected. This device size value corresponds to 85% of the prior art value, indicating a 15% reduction in device size.

This reduction is provided because by this embodiment the third photo-resist film 30 is used as a mask to remove the opaque titanium nitride film 14A as the upper capacitor electrode film, thus preventing alignment marks 26, 27, and 33 from being covered by the opaque titanium nitride film 14A.

Thus, by this embodiment, when a thin film made of a conductive or insulator film is formed on the P-type silicon substrate 1 to then repeat an alignment step using photolithography in order to manufacture the DRAM, the third photo-resist film 30 is used as a mask to remove the opaque titanium nitride film 14A as the upper capacitor electrode, and then, the fourth photo-resist film 31 formed in alignment with the alignment mark 26 on the P-type silicon substrate 1 via the first inter-layer insulator film 7 is used to form the upper capacitor electrode 14, thus enabling suppression of a misalignment.

Therefore, even if the alignment mark is covered by an opaque metal film, no limitations are inflicted on alignment, thus reducing device size.

Although the embodiment of It is apparent that the present invention is not limited to the above embodiments but may be changed and modified without departing from the scope and spirit of the invention. For example, although the above-mentioned gate insulator film, the first and second inter-layer insulator films or a like have been made of a silicon oxide film in the embodiment, any other materials may be used such as a silicon nitride film, BSG (Boro-Silicate Glass), PSG (Phospho-Silicate Glass), BPSG (Boro-Phospho-Silicate Glass) or a like. Also, the side wall insulator film may be made, besides of a silicon nitride film, of a film stack combining a silicon nitride film and a silicon oxide film or a like. Also, the gate electrode may be made of a poly-silicon film doped with an appropriate impurity or any other materials including tungsten, molybdenum, and other appropriate high-melting point metals. Also, the P- and N-conductivity types may be exchanged for the above-mentioned semiconductor regions. Also, the lower and upper capacitor electrodes and the capacitor insulator film may be made of other appropriate materials than those mentioned in the embodiment.

Although the above-mentioned embodiment has employed a CUB (Capacitor Under Bit line) structured DRAM where the capacitor is arranged under the bit line, a COB (Capacitor Over Bit line) structured DRAM may be employed where the capacitor is arranged over the bit line. Also, the DRAM can be applied not only to a standalone product but also to an LSI product in which it is arranged therein together with logic circuits. Also, the opaque metal film can be made not only of a titanium nitride film but also in any of other appropriate metal films (the metal films are generally opaque). Also, although only one example has been described of a condition for the type, film thickness, forming method of the insulator films and conductive films, the condition may be changed arbitrarily with purposes and applications.

What is claimed is:

1. A semiconductor manufacturing method for forming a thin film made of a conductive film or an insulator film on a semiconductor substrate and then repeating alignment using photolithography to thereby pattern said thin film into a desired shape in order to form a memory cell comprised of a memory cell transistor and a capacitor on said semiconductor substrate, comprising:
an alignment mark forming step for simultaneously forming a main portion of said memory cell transistor and an alignment mark in an element forming region and another region respectively on said semiconductor substrate;
a capacitor contact forming step for forming an inter-layer insulator film throughout on a surface of said semiconductor substrate and covering said inter-layer insulator film with a photo-resist film formed in alignment with said alignment mark and then locally removing said inter-layer insulator film using said photo-resist film as a mask to thereby form a contact hole which exposes a desired diffused region of said memory cell transistor and then forms a capacitor contact in said contact hole;
a thin film forming step for sequentially forming a lower capacitor electrode film, a capacitor insulator film, and an upper capacitor electrode on said inter-layer insulator film in order to form a capacitor connected to said capacitor contact; and
an upper capacitor electrode film removing step for covering said inter-layer insulator film with another photo-resist film except a region above said alignment mark of said upper capacitor electrode film and then locally removing said upper capacitor electrode film using said photo-resist film as a mask to thereby expose said inter-layer insulator film.

2. The semiconductor device manufacturing method according to claim 1, wherein said memory cell transistor and said alignment mark are formed in an element forming region and a scribe region respectively on said semiconductor substrate.

3. The semiconductor device manufacturing method according to claim 2, wherein said alignment mark is formed at the same time as a gate electrode of said memory cell transistor is formed.

4. The semiconductor device manufacturing method according to claim 1, wherein said alignment mark is formed in a number of two or more.

5. The semiconductor device manufacturing method according to claim 1, wherein after said bit contact is formed, a bit line is formed in such a manner that said bit line may be connected to said bit contact.

6. The semiconductor device manufacturing method according to claim 5, wherein said bit line is formed above said upper capacitor electrode.

7. A semiconductor manufacturing method for forming a thin film made of a conductive film or an insulator film on a semiconductor substrate and then repeating alignment using photolithography to thereby pattern said thin film into a desired shape in order to form a memory cell comprised of a memory cell transistor and a capacitor on said semiconductor substrate, comprising:
an alignment mark forming step for simultaneously forming a main portion of said memory cell transistor and an alignment mark in an element forming region and another region respectively on said semiconductor substrate;
a capacitor contact forming step for forming a first inter-layer insulator film throughout on a surface of said semiconductor substrate and covering said first inter-layer insulator film with a first photo-resist film formed in alignment with said alignment mark and then making an opening in said first inter-layer insulator film using said first photo-resist film as a mask to thereby form a first contact hole which exposes a desired diffused region of said memory cell transistor and then forms a capacitor contact in said first contact hole;
a lower capacitor electrode forming step for forming a lower capacitor electrode film on said first inter-layer insulator film in such a manner that said lower capacitor film may be connected to said capacitor contact and then covering said lower capacitor electrode film with a second photo-resist film formed in alignment with said opening in said first inter-layer insulator film and then locally removing said lower capacitor electrode film using said second photo-resist film as a mask to thereby form a lower capacitor electrode;
an upper capacitor electrode film removing step for sequentially forming a capacitor insulator film and an upper capacitor electrode film on said lower capacitor electrode and then covering said inter-layer insulator film with a third photo-resist film except a region above said alignment mark of said upper capacitor electrode film and then locally removing said upper capacitor electrode film using said third photo-resist film as a mask to thereby expose said first inter-layer insulator film;
an upper capacitor electrode forming step for covering said upper capacitor electrode film with a fourth photo-resist film formed in alignment with said alignment mark on said semiconductor substrate and then locally removing said upper capacitor electrode film using said fourth photo-resist film as a mask to thereby form an upper capacitor electrode; and
a bit contact forming step for forming a second inter-layer insulator film on said first inter-layer insulator film and then covering said second inter-layer insulator film with a fifth photo-resist film formed in alignment with said alignment mark and then making an opening in said first and second inter-layer insulator films using said fifth photo-resist film as a mask to thereby form a second contact hole which exposes a desired diffused region of said memory cell transistor and then forms a bit contact in said second contact hole.

8. The semiconductor device manufacturing method according to claim 7, wherein said memory cell transistor and said alignment mark are formed in an element forming region and a scribe region respectively on said semiconductor substrate.

9. The semiconductor device manufacturing method according to claim 8, wherein said alignment mark is formed at the same time as a gate electrode of said memory cell transistor is formed.

10. The semiconductor device manufacturing method according to claim 7, wherein said alignment mark is formed in a number of two or more.

11. The semiconductor device manufacturing method according to claim 7, wherein after said bit contact is formed, a bit line is formed in such a manner that said bit line may be connected to said bit contact.

12. The semiconductor device manufacturing method according to claim 11, wherein said bit line is formed above said upper capacitor electrode.
